(19) United States
(12) Patent Application Publication
(10) Pub. No.: US 2025/0013803 A1
(43) Pub. Date: Jan. 9, 2025

(54) A SYSTEM FOR ENTITY BASED STAGEWISE FORMAL SPECIFICATION OF PROCESSES AND A METHOD THEREFOR

(71) Applicant: Vishal Gupta, Hyderabad (IN)

(72) Inventor: Vishal Gupta, Hyderabad (IN)

(21) Appl. No.: 18/698,958

(22) PCT Filed: Oct. 4, 2022
(86) PCT No.: PCT/IN2022/050885

§ 371 Date: Apr. 5, 2024

(30) Foreign Application Priority Data
Oct. 5, 2021 (IN) 202141045332

(51) Int. Cl. G06F 30/20

(52) U.S. Cl. CPC G06F 30/20

(57) ABSTRACT

Methods and systems for entity state-based stage-wise formal specification of life science processes are provided. The method, for each such stage of a life science process, comprises specifying workflow in terms of a plurality of entities and/or batches of a plurality of entities (701) wherein entities include physical materials and digital files; applying information causing state change (702) to the at least one plurality of entities and/or batches of a plurality of entities to form its respective new entities (701′) with a modified state by way of specifying change specific parameters; generating each of the plurality of processes in their respective stages in a graphical specification comprising a plurality of layers with layer-specific information, each said layer further includes a plurality of nodes and edges, wherein layer represents each stage of the process, node of any shape or size represents one entity and/or a batch of multiple entities including their states; and edge represents information causing the state change in the entity and/or batch of multiple entities.

### FIELD OF THE INVENTION

The present invention relates to a system and method for design and execution of life science processes, in particular, design and implementation of physical and digital processes via automated tools.

### BACKGROUND OF THE INVENTION

Researchers across multiple disciplines in the life science domain have their own custom workflows which have been developed and fine-tuned to their requirements. Though these workflows vary across disciplines, they can be simplified and grouped into the following stages—
Stage 1: Hypothesizing or Ideating—Researchers, depending on their field of expertise, read the relevant literature, and form a hypothesis which if tested and proved can explain the behaviour of a system.
Stage 2: Experiment Design—They design robust experiments which upon conducting or executing, can prove or disprove their hypothesis with certainty.
Stage 3: Planning Experiments—The infrastructural requirements like reagents, samples, instruments, compute and data storage needed to conduct the experiment are procured or arranged.
Stage 4: Executing Experiments—The designed experiment along with the required infrastructure is performed/executed as per specified methodology in the experimental design and all the data and observations are carefully gathered.
Stage 5: Analysis—The results of the experimental execution are carefully analysed, taking into account all possible biases to check if the results confirm the hypothesis.

If the outcome is successful, the researcher publishes the results. If the outcome is unsuccessful or inconclusive, the researcher either goes back to Stage 1 to read and refine the process and repeats the rest of the stages. These 5 stages depending upon the domain (e.g. Synthetic Biology) are sometimes referred to as the Design, Build, Test and Analyse (DBTA) cycle or the Design, Build, Test and Learn (DBTL) cycle. Irrespective of how these cycles are referred to in different domains, Stage 1-5 are commonly observed across all domains. Every cycle of this workflow needs to be meticulously documented for troubleshooting and ensuring reproducibility. However, this is very difficult and it is only recently that researchers have begun to address the elephant in the room which is non-reproducibility of research.

Research and development in life sciences is plagued with non-reproducibility of results. Non-reproducibility of research is a critical problem as it slows down the time to market of drugs, biomolecules, cleaner bio-alternatives in industry etc., and hinders human knowledge and progress. There are studies and surveys which state that less than 70% of the researchers failed to reproduce other researcher's work [1]. We are losing hundreds of billions of dollars to non-reproducibility annually, and therefore it is critical that we develop novel tools and approaches to solve this issue.

There are many reasons which cause non-reproducibility and the reasons can also be very specific or unique to the type of research i.e. wet-lab or computational research [2], and specific to the domain of research e.g. psychology [3], neuroscience [4], cancer biology [5] and drug discovery [6]. For research being done in bio-medical, biological and chemistry and its respective sub-domains which include both wet-lab and computation type of work, the primary causes of non-reproducibility are can be attributed to the following:
Lack of adequate tools—The digital tools available today capture information which are specific to one or more stages (see stages 1-5).
   a) Experiment design and results are captured using Electronic Lab Notebooks. These notebooks are text-editors or code editors similar to Microsoft Word or Google Docs and Visual Studio.
   b) Information about Laboratory Inventory is captured using Laboratory Inventory management systems. These systems capture information about the available inventory and its usage.
   c) Information about experiment design and inventory together is captured using Lab Information management systems or Laboratory Informatics Systems. These information systems allow capturing information about two stages at the same time.
   d) Information about experiment planning and execution is captured using Laboratory Execution Systems. These systems focus more on executing experiments in a manual or automated manner and the underlying hardware used.
   e) Data generated is analysed using user specific analysis tools and they are captured in tool specific formats and stored separately.

There are multiple tools available which capture one or more stages in different combinations. These tools can also be integrated together to form an end-to-end custom solution. However, working with these tools is cumbersome for users as they are difficult to set up and not seamlessly connected which forces the user to modify their natural research workflow to adapt it to the available solutions. This discourages the users from using tools which increases non-reproducibility. Furthermore, the tools are also very expensive and difficult to maintain. Some tools also require system administrators for setup and maintenance which adds to the cost.

Lack of adoption of common standards/format for information storage—Different tools store information in different proprietary formats which makes it very difficult for users who are working with two different tools to exchange and work with the data. This silos users based on the tools they use and exacerbates the non-reproducibility problem. There are continuous attempts to use open-source standards but such standards have limited adoption because of a very high cost of switching from legacy solutions [7].

Limitations of information sharing medium—Currently research information is disseminated by publishing in scientific journals. These journals put multiple restrictions on the users in terms of publishing formats and article size in page numbers and words which limits the users from sharing their complete research which is critical for reproducibility. Even though journals are evolving their tools, the new tools push the burden on the users to store different types of data in different tools like university or institute specific repositories, public repositories like gitHub (for code) or inside supplementary information which is attached to journal articles. It becomes a tedious task for interested researchers to find and access this data on multiple platforms. The tools are not always easily accessible and the information stored loses context when stored across multiple tools.

Multiple Stakeholders with limited cross-domain knowledge—Research is increasingly multi-disciplinary and involves researchers, technicians from various backgrounds to work together and have an understanding of each other's work. Since, different disciplines use different tools which are preferred in their domains e.g. Perl programming for bioinformatics, Python and C is preferred by computational scientists, R is preferred by statisticians, it becomes very difficult to share, investigate and reproduce other user's research work.

Lack of common infrastructure—Different users require different wet-lab (labware, instrumentation etc.) and different computational (Operating Systems, libraries, applications, compute and storage capacity) infrastructure to perform their research. It is very difficult for researchers to be able to reproduce research, as the research specification is tied to infrastructure used. Translating or porting research to other platforms/infrastructure is a tedious task and requires a lot of effort in optimisation.

Communication gap—Research is a global initiative and researchers globally publish their research work and progress in scientific journals. The de-facto standard of written research communication is in Natural Languages like English. There are also multiple other languages in which research is published like Japanese, Mandarin and Spanish. Natural languages (like English) are not the best medium for communication, as they can be easily misinterpreted. The communication can be incorrect depending on the researcher's command over the language (eg. native and non-native speakers), ability to articulate an idea, difference arising when translating from their native language to English. This problem is further amplified when technical and non-technical information is intentionally or unintentionally omitted from the communication. This leads to incomplete information and makes it very difficult for other researchers to reproduce a research work and further build on it.

Formal languages (e.g. XML, JSON), programming languages (eg. C, C++) and other high-level languages (e.g. Python, Domain Specific Languages) are useful for communicating accurately with hardware. However, the use of such languages to communicate research methodology and results would be less than ideal. These languages are accurate but very verbose, so it is a trade-off between case of use and accuracy [8].

Further, it is pertinent to note that current specification format tools of wet-lab and computational experiment designs available are very hardware dependent. The names of the physical instruments and software applications/libraries are required to be specified in the experimental design along with parameters and terminology unique to them. This is a major problem when trying to reproduce the experiment design using a similar but different instrument or application. For example, certain instructions like ‘Pipette 2 ml of Sample from Eppendorf A to 1.5 ml Eppendorf B’—here, Pipette is the name of the instrument but for it to be clearly understood/interpreted by other stakeholders it should be replaced with the term ‘Transfer’. Further, ‘Eppendorf A and B’ refer to tubes containing the samples. To ensure that the experiment designs are not misinterpreted by other people, it is required to use terminology which is easily understood by people viewing and using the specification format. Currently, there are no such standards existing. Notwithstanding the above, in order to ensure that the designs are future proofed viz. they do not get obsolete as hardware evolves (Ex.: Milifluidic, microfluidic, nanofluidic platforms), it is required to abstract the experimental design from the execution hardware. This will ensure longevity and portability of experimental designs.

Further, use of natural language for communicating research, especially experimental designs are not optimal. There have been attempts to use graphical specification but it's limited to specific stages and has a very narrow objective [9]. We critically need an unambiguous method of communication of different stages of the research workflow.

It is thus the objective of the present invention is to provide a system that overcomes the above issues, problems and drawbacks of the existing tools. Further described herein in relation to one or more embodiments, are the methods and systems are provided for generating entity state-based stage-wise formal specification of processes and a method thereof.

### OBJECTIVES OF THE INVENTION

One of the primary objectives of the present invention is to reduce research non-reproducibility using an easy-to-use graphical research specification system that allows researchers to accurately specify their research in different stages of their workflow with minimal effort. The specification system addresses all the previously described causes of non-reproducibility of research including lack of adequate tools, lack of common standards/format for information storage, limitations of information sharing medium, multiple stakeholders with limited cross-domain knowledge, lack of common infrastructure and communication gap.

Another objective of the present invention is to provide a computer-implemented system and method for generating graphical formal specification based on entity states for each stage of any life science processes.

Another objective of the present invention is to provide a graphical specification system focussing on the entity and the automatic generation of its subsequent states upon application of any change rather than the changes and their processes tied to specific hardware.

Yet another objective of the present invention is to provide a graphical specification system that allows any type of entity viz. physical materials and digital files unlike other existing specification systems which allow specification of only one or the other type of entity.

Still another objective of the present invention is to provide a graphical specification system that aids in debugging/troubleshooting and reproducing the experiment in different stages of the workflow.

### SUMMARY OF THE INVENTION

The present invention has overcome the problems associated with the prior arts by providing methods and systems for reproducible and scalable process workflows. Accordingly, the first aspect of the present invention provides a method for generating graphical specification of process design, planning, execution and analysis stages of a plurality of life science processes, for each such stage of the plurality of life science processes. The said method comprising the steps of specifying workflow of the process in terms of a plurality of entities and/or batches of a plurality of entities wherein entities include physical materials (including reagents, patient samples, cells, tissues, organs, animals, chemicals etc., in solid or liquid form) and digital files (including images, genome sequences, protein sequences etc.); applying information causing state change to the atleast one plurality of entities and/or batches of a plurality of entities to form its respective new entities with a modified state by way of specifying change specific parameters change specific parameters (including quantity manipulation, transformation and measurement for physical materials, and data manipulation and visualization for digital files); and generating each of the plurality of processes of their respective stages in a graphical specification comprising a plurality of layers with layer-specific information, each said layer further includes a plurality of nodes and edges, wherein layer represents each stage of the process, node of any shape or size represents one entity and/or a batch of multiple entities including their states; and edge represents information causing the state change in the entity and/or batch of multiple entities.

The method further enables at least two processes to be combined to form a complex process by merging and/or linking their boundary nodes for arrangement of the said processes in sequential order or to create a single process; at least one step in the at least one process of the plurality of processes to be traversed by a certain pre-selected time point to minimize its execution time; and at least one process is automatically translated to a preferred natural language for further processing by a human.

The second aspect of the present invention provides that nodes of the graphical specification are mapped to materials and data, and edges are mapped to compatible instruments and software applications during the planning stage of the process.

According to the third aspect, instrument-specific execution instructions are automatically sent to instruments during process execution so that configurable virtual machines are deployed on the cloud or locally for applications. The entire virtual machine is saved for future use along with data, dependencies and environment. Further, all data generated during the process execution is stored in the context of the respective edge and is represented on the node. The said data can then be visualised and analysed in the analysis stage in the analysis section using configurable virtual machines.

Fourth aspect of the present invention provides a system for generating graphical specification of process design, planning, execution and analysis stages of a plurality of life science processes, for each such stage of the plurality of life science processes.

### BRIEF DESCRIPTION OF THE INVENTION

The invention is further described in the detailed description that follows, by reference to the noted drawings by way of illustrative embodiments of the invention, in which like reference numerals represent similar parts throughout the drawings. The invention is not limited to the precise arrangements and illustrative examples shown in the drawings:

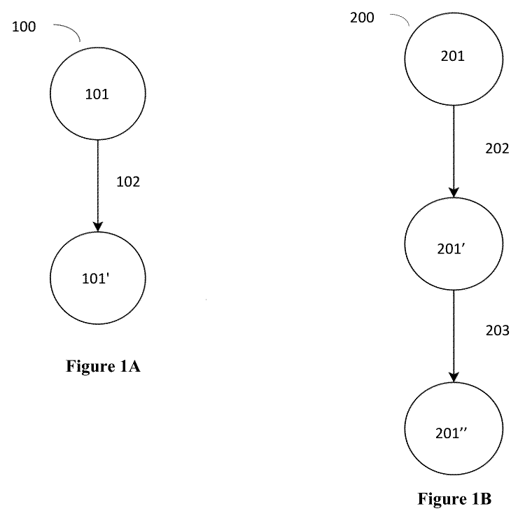

FIG. 1A and FIG. 1B shows the different components of a process in the present graphical specification format;

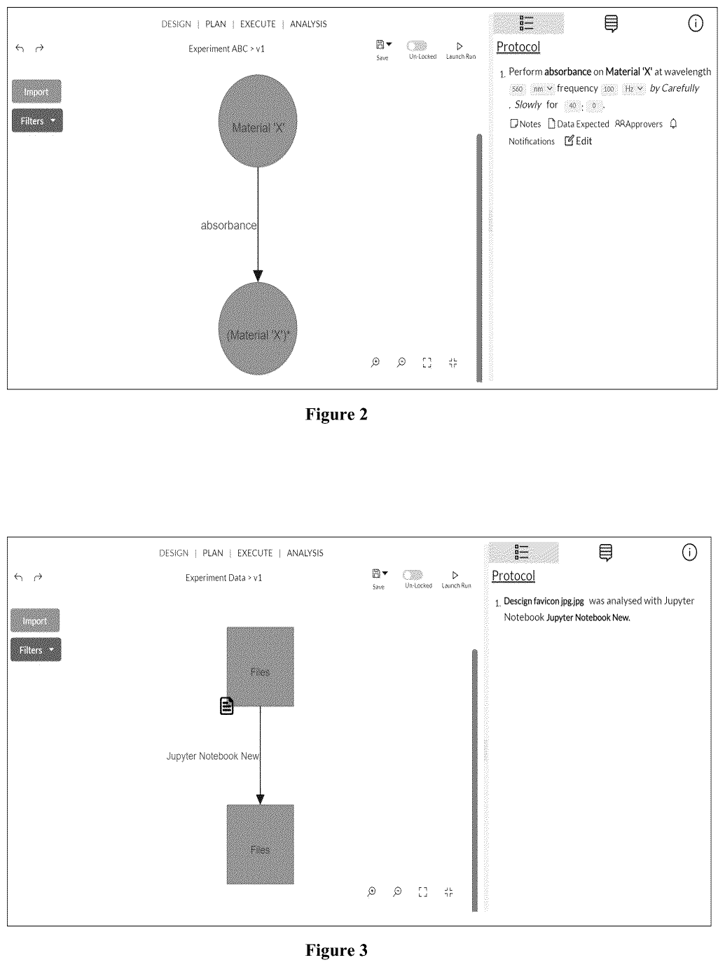

FIG. 2 shows the interface of the present system wherein a process of state change of a physical material is illustrated in graphical specification format along with its corresponding explanation in natural language;

FIG. 3 shows the interface of the present system wherein a process of state change of a digital file is illustrated in graphical specification format along with its corresponding explanation in natural language;

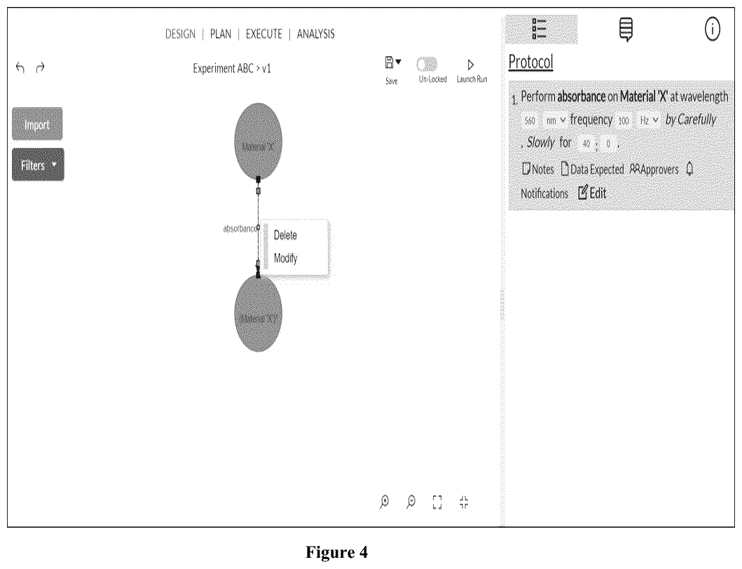

FIG. 4 shows the interface of the present system wherein process of editing a state change is illustrated in graphical specification format along with its corresponding explanation in natural language;

FIG. 5 shows merging of two independent processes in accordance with one of the embodiments of the present graphical specification format;

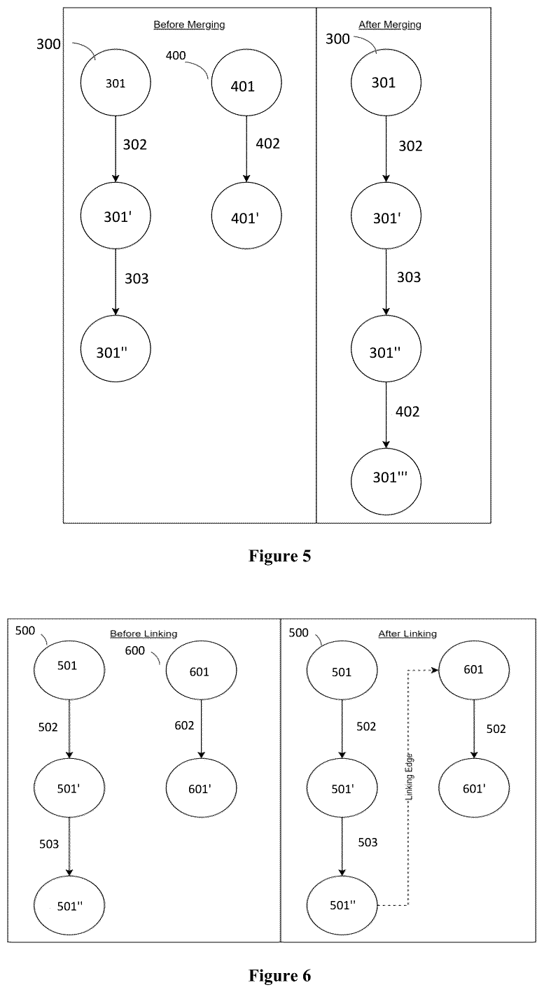

FIG. 6 shows linking of two independent processes in accordance with one of the embodiments of the present graphical specification format;

FIG. 7 shows the interface of the present system wherein process of addition and deletion of steps including linking and merging steps is illustrated in graphical specification format along with its corresponding explanation in natural language;

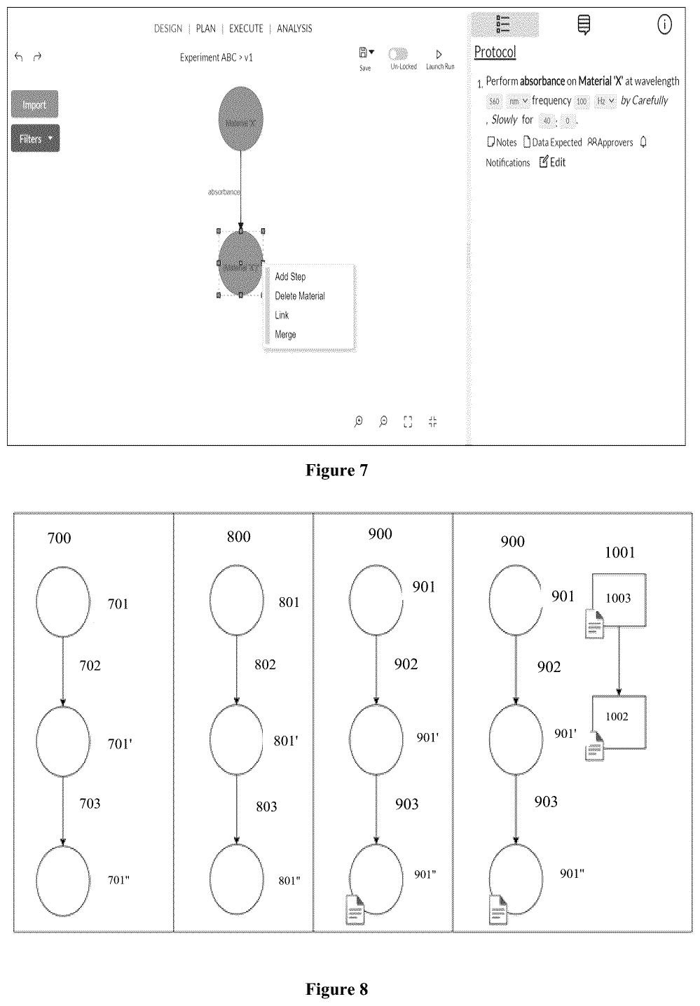

FIG. 8 illustrates stage-wise graphical specification representation of a life science process in accordance with the present system;

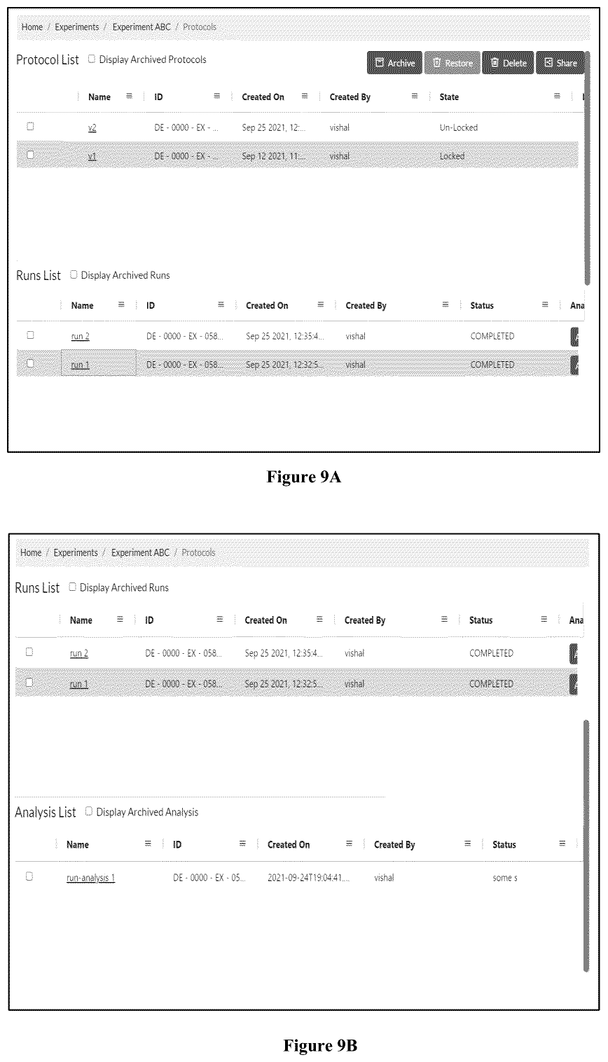

FIGS. 9A and 9B shows the interface of the present system illustrating the hierarchical and organised structure of storing, retrieving and modifying processes in different stages;

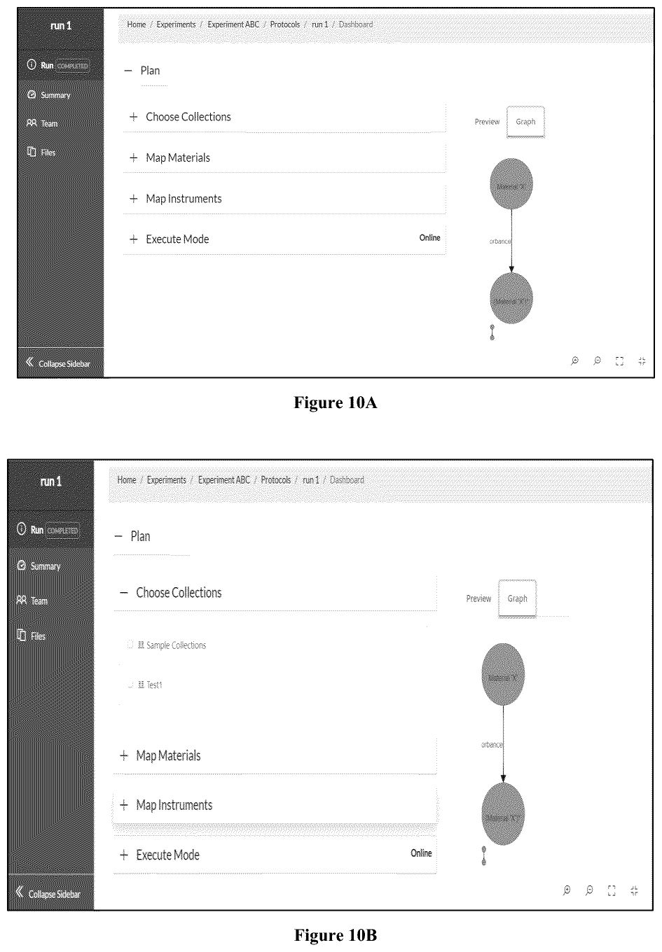

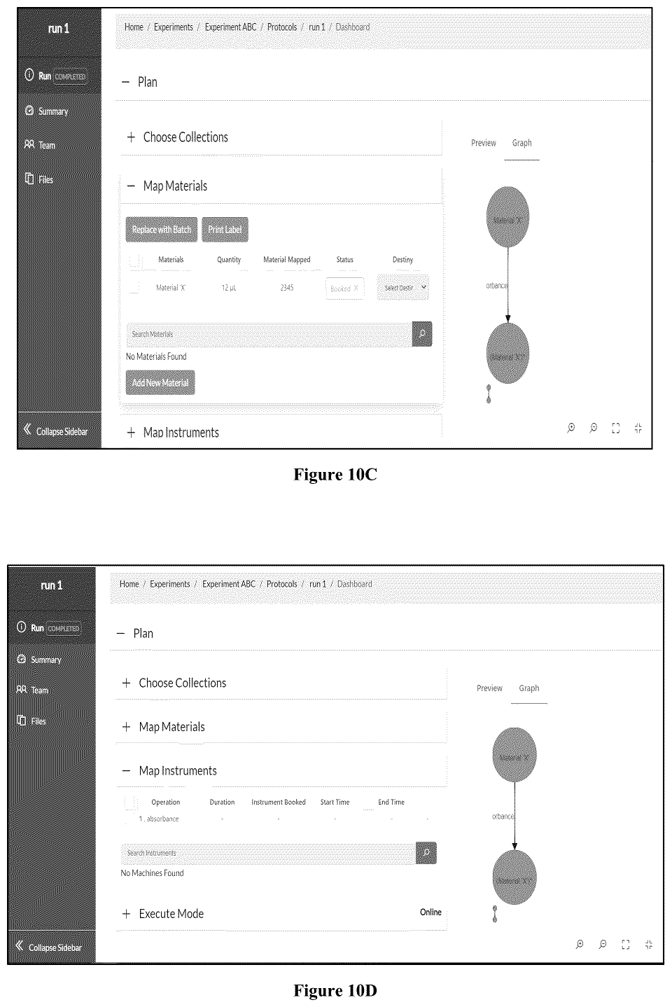

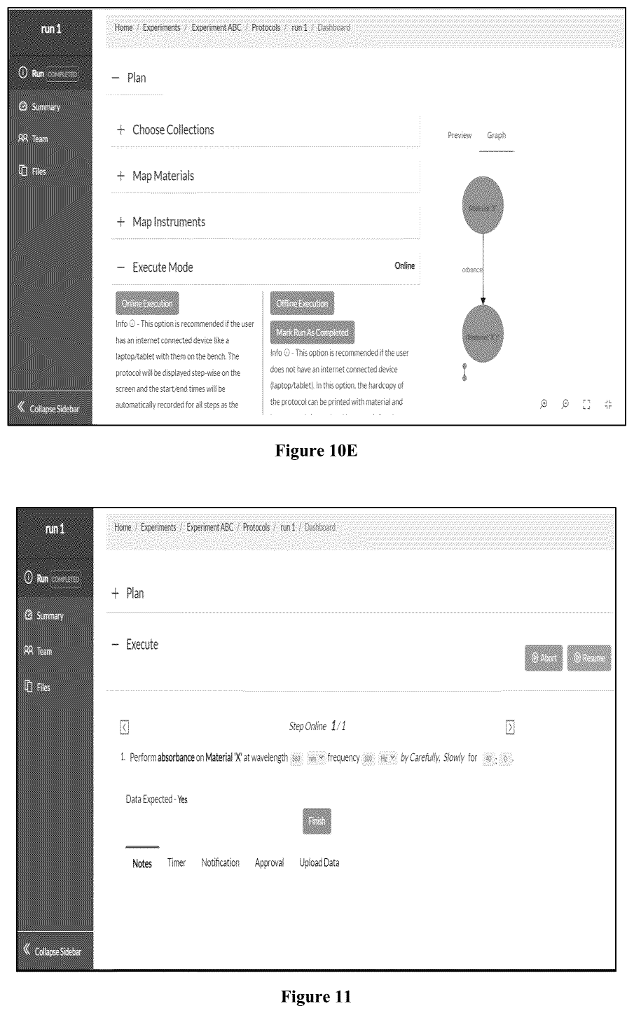

FIG. 10A-E shows the interface of the present system illustrating how details of mapped materials/files including booking durations are captured and maintained for every experimental design version selected to be executed;

FIG. 11 shows the interface of the present system illustrating automatic generation of natural language instructions from the graphical specification of the process;

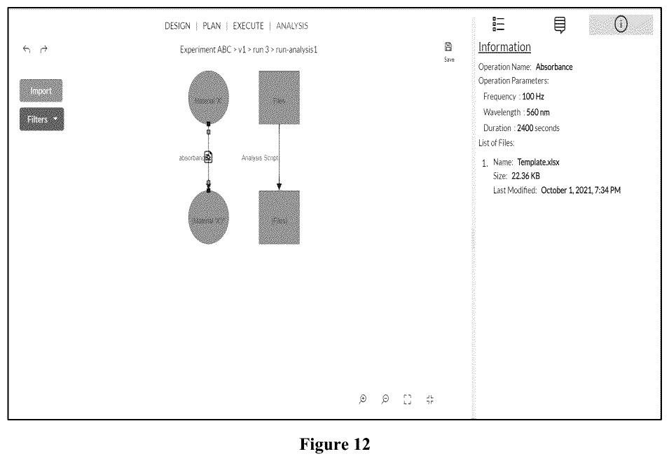

FIG. 12 shows the interface of the present system illustrating process in the Run Analysis stage;

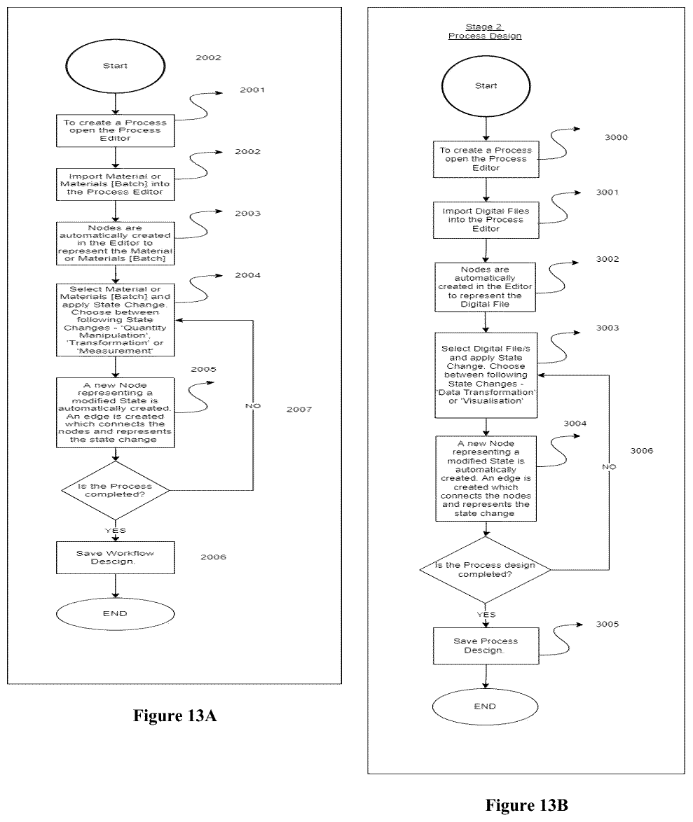

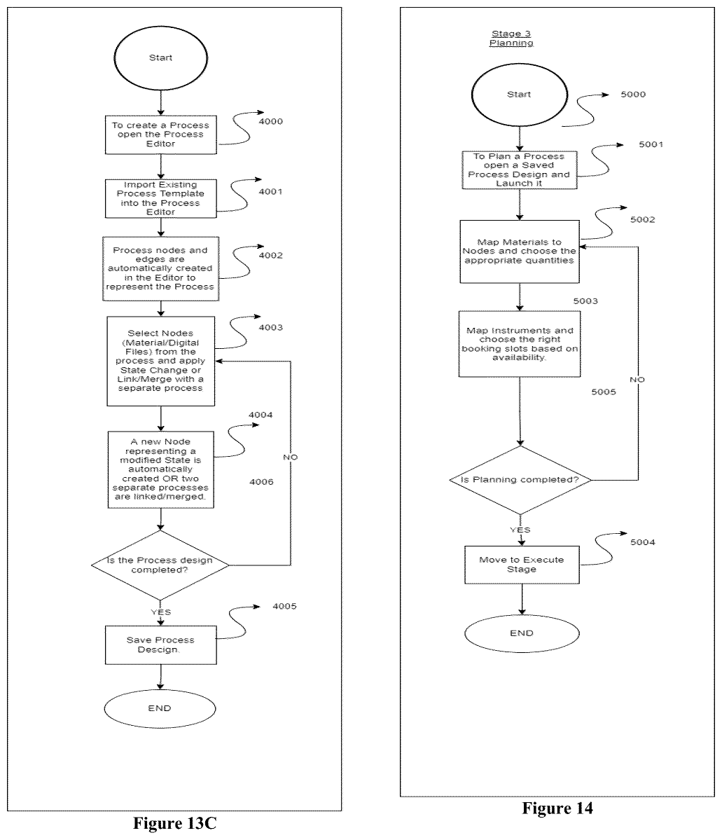

FIGS. 13A, 13B and 13C show flowcharts of method of designing a life science process by way of specifying experimental designs based on a plurality of entities and state changes applied thereto;

FIG. 14 shows flowchart of method of planning of a life science process wherein the designed process is mapped with appropriate quantities of materials and instruments used;

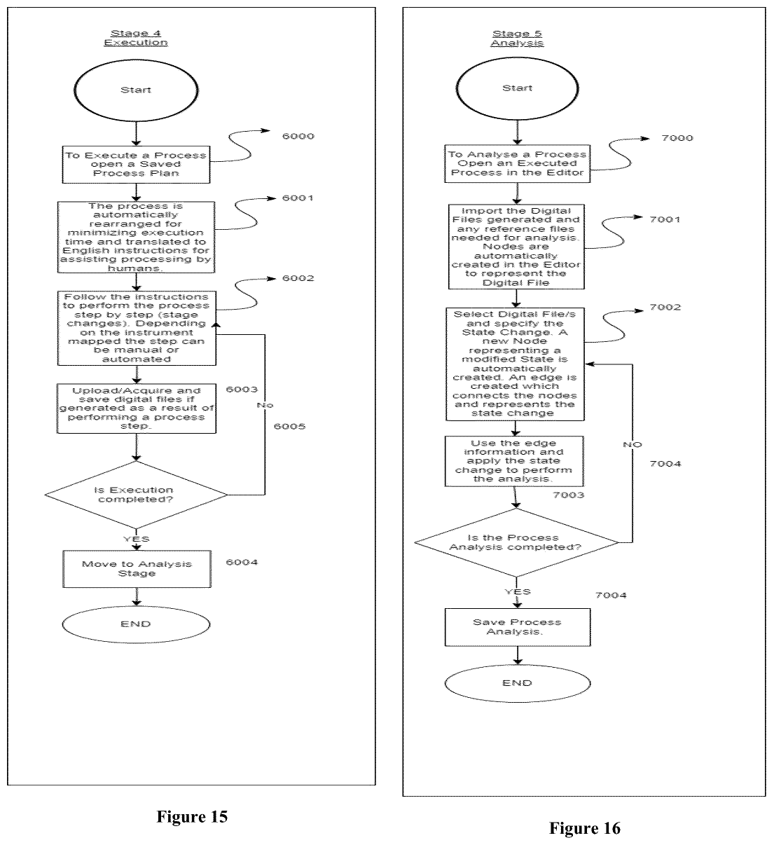

FIG. 15 shows flowchart of method of execution of a life science process; and

FIG. 16 shows flowchart of method of analysis of a life science process.

### DETAILED DESCRIPTION OF THE PREFERRED EMBODIMENTS

Detailed embodiments of the present invention are disclosed herein with reference to the drawings. However, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting but rather to provide an understandable description of the invention.

The present invention discloses a graphical specification system enabling users to specify their research workflow and capture such detailed information with a focus on crucial stages of life science processes viz. experiment design, planning, execution and analysis. Currently available approaches are limited to using text editing tools for research workflow specification. However, the present invention proposes an entity-state change based graphical system for specification of experimental designs.

According to one of the embodiments of the present invention, the system enables users to specify their experimental designs based on/using a plurality of entities (101) and a plurality of state changes (102) that are applied to the respective entities as shown in FIG. 1A. For instance, the entities (101) in graphical specification (100) include physical materials and digital files. Physical materials are substances that are required to initiate the experiment, which may include materials of biological, chemical and biomedical origin such as sub-cellular components, single or multicellular organisms, tissues, organs, animals in whole or parts, human patient samples, antibodies, reagents, buffers, dyes, etc., individually or as complex mixtures thereof, in solid, liquid or gaseous form. Digital files are any electronic files of biological data (e.g. sequence files), chemical data (e.g. molecules), compound libraries, experimental data in multiple formats like tables (e.g. CSV), images (e.g. jpeg), audio and video.

According to another embodiment of the present invention, the plurality of entities that are specified in experimental designs as above are represented as ‘nodes’ in the graphical specification format, which are of any shape and/or size. A node/vertex is used to represent a single entity or a batch of multiple entities and their states. The shape of the node is customizable, for example, square, circle and polygon. Further, state changes (102) being applied to respective entities automatically creates a new entity with a modified state (101′).

Such state changes (102) for a physical material can be categorized into quantity manipulation, transformation and measurement. Quantity manipulation includes, without limitation, transfer, adding and subtracting similar or dissimilar quantities of the same or different materials. Transformation includes, without limitation, moving, heating, cooling, incubation and mixing materials. Measurement is used to investigate and estimate different biological, chemical and physical properties of materials and includes, without limitation, weighing, imaging, spectroscopy, sequencing and calorimetry. Changes for a digital file includes data manipulation and visualization wherein data manipulation includes, without limitation, data extraction, wrangling, cleaning, preparation, statistical analysis; and said data visualization further includes generating figures of biological, chemical, medical and experimental data in the form of sequences, structures and models, to identify trends to gain a better understanding of the data. These changes (102) are represented by edges in graphical format, and require change specific parameters to be specified to change the state of an entity.

Edges connect entities to their states, and they represent information which causes the state change in the entity material. Entities can have multiple outgoing and incoming edges connecting to their respective new states.

It is to be noted that the present system focuses on the entity (node) and the automatic generation of its subsequent states upon applying a change (edge). Other specification formats focus on the change (edge) and their processes which are usually tied to specific hardware. The advantage of using an entity-based graphical specification format is that it is independent of hardware (containers, instruments and equipment) used for executing the process. Here, the hardware is mapped separately at a later stage. As a result, the present system allows different types of execution such as manual, semi-automated and automated, depending upon the availability of compatible hardware and drivers.

According to another embodiment of the present invention, entities viz. nodes (201) and their respective state changes viz. edges (202 and 203) together represent a process (200) in a graphical specification [Refer FIG. 1B]. In other words, a node (entity) joined by an edge to its new state creates a minimal process. A process shall include at least one entity (201), at least one state change (202/203) applied to the said entity and a resultant new entity state (201′/201″). A process can further be made of multiple minimal processes or multiple steps that have a plurality of entities, their respective changes and respective resultant entity states. Multiple entities (viz. physical, digital, batch) can be joined together to create longer complex processes. All these processes serve as templates and can be completely modified. Entities can be switched and the changes can be modified too in a process. This serves as a useful tool for users/research groups wherein they have standardised certain processes that need to be executed multiple times but for different samples. Ex: A process of preparation of plasmid, DNA extraction, sequence analysis, etc.

In one of the illustrations as shown in FIG. 2, physical material—(Material ‘X’) is represented as a node (circle) in the canvas (left box). A state change with specific parameters is applied to the material and it creates a new node which represents the material with the state change applied as (Material ‘X’)'. The state change (absorbance) is represented as an edge (arrow) and it connects the two nodes. The whole step is automatically translated to English with the state change parameters as shown in the right box of FIG. 2.

In FIG. 3, a digital file is represented as a node (square) called ‘Files’ in the canvas (left box). A state change with specific parameters is applied to the Files to create a new node which represents any output files generated as a result of the state change applied. The state change viz. Jupyter Notebook New is represented as an edge (arrow) and it connects the two digital nodes. The whole step is automatically translated to English with the details of the state change in the right box of FIG. 3.

Further, FIG. 4 shows the process of editing i.e. deleting or modifying a state change per the aforementioned embodiments of the present invention. Users can edit state change parameters by either clicking on the specific state change edge or by clicking on the edit button in the English translation of the step.

According to another embodiment, certain processes are modular in nature viz. a process can be attached to other processes to form a longer complex process. The present system allows only two processes to be attached at a single time. Processes are combined by attaching them to each other by their respective boundary nodes. According to such embodiment, boundary nodes are of two types viz. (i) starting/parent/zero/initial state nodes and (ii) child/edge/final state nodes. As the name suggests, starting/parent/zero/initial state node is a node that is present at the beginning of a process; and child/edge/final state node is a node that is present at the tail end of a process. A parent node of one entity can be switched/replaced with another entity of the same type i.e. physical entity with a physical entity and a digital entity with another digital entity. Depending on the process requirements, the attachment as suggested above is done by way of merging or linking two processes.

With reference to FIG. 5, when two independent processes (300 and 400) are combined by way of overwriting a child node (301″) of one process (300) by a parent node (401) of the other process (400), it is called Merging. Merging fuses two independent processes (300 and 400) to create one single process (300). In other words, merging is used to create a single process where entities need to undergo further multiple changes (302 to 303 to 402) in a sequence. Merging is applicable only for physical entities/nodes. When two independent processes (500 and 600) are combined by way of linking a child node (501″) of one process (500) to a parent node (601) of the other process (600), it is called linking per FIG. 6. This tool links two processes (500 and 600) and arranges them in a sequential order in time. Linking indicates the order of two processes which are connected or related to each other temporally (based on time). The processes can be cyclical, acyclical or directed.

FIG. 7 shows the process of adding steps to a process, deleting steps, linking and merging steps per the embodiment details in the previous paragraphs. Users can click on a child/end node and choose the appropriate action they want to take.

In accordance with yet another embodiment of the present invention, depending on the requirements, users will be able to time-order a process to minimize the time of execution or to complete/traverse different steps involved in a process by a certain pre-selected timepoint. Such time-ordering is done using standard methods of calculating the duration required for different steps and trying to minimize or maximise the process traversal time. The processes can be traversed/executed subject to conditions which are captured as a part of edges. The conditions can be parameters which need to be satisfied or met or it can be explicit approval required by a user for further traversal of the process. The processes can be automatically sorted to minimize or maximise time of traversal/execution. This is useful to minimise time of execution for complex long processes which have multiple branches.

In accordance with yet another embodiment of the present invention, the graphical specification system as disclosed removes the requirement of specification of hardware during the experimental design specification stage of a process (viz. Stage 2). It allows users to map the hardware of their choice in the planning stage (viz. Stage 3). Depending upon the availability of hardware infrastructure (viz. instruments, software applications, compute and storage), users can map compatible hardware to different steps in a process to execute their experimental designs seamlessly. In other words, during process planning, nodes can be assigned/mapped to materials and data and edges can be mapped to compatible instruments (e.g. thermocyclers, sequencers) and software applications. Any extra parameters required for execution are added during the planning and/or execution stage of such process (viz. Stage 4). During process execution, instrument-specific execution instructions can be automatically sent to the instruments and configurable virtual machines can be deployed on the cloud or locally for applications. The entire virtual machine is saved for future use along with data, dependencies and environment. The data can then be visualised and analysed in the analysis stage in the analysis section using configurable Virtual machines.

The present system enables hardware specific input requirements to be prompted to the researcher (technical operator) performing the experiment. This allows experimental designs to be executed manually by a human operator, or in a semi or fully-automated manner on a robotic platform. Another advantage of this hardware abstraction is to be able to capture information in the context of the hardware used which helps in troubleshooting or debugging the experiment.

Still another embodiment of the present system enables all data generated during the experiment to be captured and stored in the context of the step it was generated. The graphical specification system takes into account the stages of the research workflow and attaches stage specific information to the process. This makes it very useful for debugging/troubleshooting and reproducing the experiment in different stages of the workflow. Researchers can analyse the data (viz. Stage 5 of the process) generated using software applications of their choice with customisable compute configuration like CPU capacity and memory capacity. All the resulting data from the analysis is further automatically y stored in a resulting node.

An illustration of stage-wise representation of a process on the present system is embodied in FIG. 8. In the experimental design stage of the process (700), Sample A (701) is being subjected to certain state changes viz thermocycle at 92° C. for 2 minutes subsequently at 92° C. for 30 seconds, 72° C. for 50 seconds and 62° C. for 70 seconds, which is then repeated for 40 cycles (702). Thermocycling of Sample A (701) at such mentioned parameters (702) will produce Sample A′ (701′). Further, measurement of Optical Density of Sample A′ at 560 nm (703) will produce Sample A″ (701″).

In the planning stage (800), 50 μl of Sample A (801) is amplified under a PCR machine (802), the resulting sample A′ (801′) of which is further subjected to a spectrophotometer (803). Here, 50 μl of Sample A of planning stage (801) is mapped to Sample A of design stage (701), and it will be amplified using the PCR machine (802) which is mapped to Thermocycle (702), the resulting sample A′ (801′) is further subjected to a spectrophotometer (803) which is mapped to the Measure OD (703), which results with the final Sample A″ (801″).

In the execution stage (900), 50 μl of Sample A of execution stage (901) is amplified using the PCR machine (902) with the required parameters, which results in an amplified (state changed) Sample A′ (901′). The Sample A′ of execution stage (901′) is further measured using a spectrophotometer with the required parameters (903) which results with the final Sample A″ (901″). The final step also results in a data file/s (901″) which is stored in the context of spectrophotometer edge (903).

In the analysis stage, data file/s generated as result of spectrophotometer state change (903) is analysed. The data file/s represented as a single node (1000) and other relevant/reference files are analysed using a software application of choice (1003) which results in a new node (1002/1001′) where all the modified and any new files generated are stored.

Each stage (Stage 2 to Stage 5) of the research workflow is a separate layer appended to the graphical specification system of the present invention. Attaching a layer to the graphical specification system automatically captures layer-specific information with very granular context, which aids in reproducibility of the research work. This feature is being explained with reference to certain exemplary illustrations as below.

In the Experimental Design layer (viz. Stage 2), along with experimental design, in particular, process details of materials/data and state change applied, versioning of the processes are maintained. Versions behave like standalone and independent experiment designs. Each version has its own set of layers. FIGS. 9A and 9B show the hierarchical and organised structure of storing, retrieving and modifying processes in different stages. ‘Protocol List’ section shows how experiment designs are versioned and displayed. When a specific version e.g. ‘v1’ is selected, its corresponding runs ‘run 2’ and ‘run 1’ are displayed in the ‘Runs List’ section. A ‘Run’ comprises of planning and execution stages as shown in FIG. 10A. When a specific Run e.g. ‘run1’ is selected, its corresponding analyses are displayed in the Run analysis section e.g. ‘run-analysis 1’ (refer FIG. 10A). Users can choose a process in its corresponding stage to go to graphical representation. Users can alternatively access all the relevant data of any process using the file navigation system.

In the Planning Layer (viz. Stage 3) for every experimental design version selected to be executed, details of mapped materials/files including booking volumes and mapped hardware including booking durations are captured and maintained as shown in FIG. 10A-E. FIG. 10A shows the different steps/stages a process undergoes in the Planning Stage (viz. Stage 3). In FIG. 10B, users can choose from a collection of predefined entities to map to the process. In FIG. 10C, the entities in the process undergo mapping, where quantity and destiny of the mapped material is specified. In 10D, the state changes in the processes are mapped to compatible hardware (instruments) along with specification of the booking details. In FIG. 10E, users can choose to execute the process online where step by step English instructions or robotic instructions are generated to be used by the operation or hardware platform. They can also choose to implement the process offline without the assistance of automatically generated instructions.

Further in the execution Layer (viz. Stage 4) for every planned experimental design version, its execution details are captured and maintained. FIG. 11 shows an example of natural language instructions generated automatically from the graphical specification of the process. Users have the provision of uploading the files during execution or later in the context of the step for which the data was generated. The information includes without limitation, the start and stop timings at the process and step level, users who performed the steps, data generated for each of the steps which is stored with the context i.e. it is linked to each step. To simplify findability, navigation and contextuality of data, the data is represented as a satellite node adjacent to the main node. Users can easily find the data for all the steps in which data was generated, just by viewing the graph. Alternatively, researchers can also find the data by navigating the file system which stores the information in the appropriate folder location.

In the Analysis Layer (viz. Stage 5) all the data generated in the execution layer is highlighted on the graph and is available to be analysed using different tools. FIG. 12 shows the process in the Run Analysis stage. Data generated during the execution is highlighted using nodes/icons over the edge. Users can click on the edge to see the information corresponding to file/s generated and stored for a particular step. The files can be imported to be analysed using different software solutions. The imported files are represented as digital nodes and the software solution used for analysis is shown as the edge.

According to still another embodiment of the present invention, the system automatically translates the process specified in the graphical specification format to natural language (viz. English or any other language of choice) and/or formal language/code (viz. XML, Python, JavaScript, etc.) for further processing by a human or a compatible robotic platform respectively. Each step of the process is translated which contains all the information needed to perform the experiment.

According to the other aspect of the invention, the present invention also discloses a computer-implemented method enabling users to specify research work flow and capture such detailed information with a focus on crucial stages of life science processes viz. experiment design, planning, execution and analysis. In particular, the present invention further discloses an entity-state change based graphical method for specification of experimental designs.

In the process design stage, users may specify their experimental designs based on/using a plurality of entities and a plurality of state changes that are applied to the respective entities. In one of the embodiments as in FIG. 13A, the method of specifying design (2000) includes creating a process through input unit viz. process editor (2001). The required physical material or batches of physical materials are imported into the process editor (2002) upon which nodes are automatically created to represent such selected physical material or batches of materials (2003). The required nodes representing material/batch of materials are selected for changing its state viz. quantity manipulation, transformation and measurement (2004). Quantity manipulation includes, without limitation, transfer, adding and subtracting similar or dissimilar quantities of the same or different materials. Transformation includes, without limitation, moving, heating, cooling, incubation and mixing materials. Measurement is used to investigate and estimate different biological, chemical and physical properties of materials and includes, without limitation, weighing, imaging, spectroscopy, sequencing and calorimetry. Upon application of such state change, a new node representing a modified state viz. an edge is created connecting the nodes and representing the state change (2005). If the process is completed, the created workflow is saved (2006) else, the process of selecting a new material and creating respective nodes and edges are repeated (2007).

In another embodiment of the present method (Refer FIG. 13B), the specification of process design is done through digital files (3000). The said method includes importing digital file(s) into the process editor (3001) thereby creating respective node(s) representing the said digital file(s) (3002). The required nodes representing digital file(s) are selected for changing its state viz. data transformation/manipulation and/or visualization (3003) wherein data manipulation includes, without limitation, data extraction, wrangling, cleaning, preparation, statistical analysis; and said data visualization further includes generating figures of biological, chemical, medical and experimental data in the form of sequences, structures and models, to identify trends to gain a better understanding of the data. Similarly, upon application of such state change, a new node representing a modified state viz. an edge is created connecting the nodes and representing the state change (3004). If the process is completed, the created workflow is saved (3005) else, the process of selecting a new digital file(s) and creating respective nodes and edges are repeated (3006).

In yet another embodiment of the method of creating a process (4000) as in FIG. 13C, any existing process template (with physical material and/or digital files) is imported (4001) into the process editor to create respective nodes and edges (4002). Thereafter, relevant state change is applied to the selected nodes and/or link/merge two separate processes (4003). Further, a new node representing a modified State is automatically created and/or two separate processes are linked/merged (4004). If the required merging/linking process is completed, the created workflow is saved (4005) else, the process of selecting new material/digital file(s) and creating respective nodes and edges are repeated (4006).

In yet another embodiment (refer FIG. 14), the method of planning a process (5000) includes launching the saved process design (5001) to map materials to nodes and choose the appropriate quantities (5002) followed by mapping instruments and choosing the right booking slots based on availability (5003). If the planning is completed, the user is taken to the execution stage (5004). If not, step (5002) is repeated (5005).

Still another embodiment of the method (as in FIG. 15) includes a method of executing the designed and planned process (6000). The selected saved and planned process is automatically re-arranged for minimizing execution time and is translated to English instructions for assisting processing by humans (6001). The provided instructions are followed to perform the process step by step wherein the step can be manual or automated depending on the instrument mapped (6002). The method may include uploading digital files that are generated as a result of performing a process step (6003). If the execution is completed, the user is taken to the analysis stage (6004). If not, step (6002) is repeated (6005).

Still another embodiment of the method (as in FIG. 16) includes a method of analysing the data generated during the execution process (7000). The said method includes importing digital file(s) into the process editor thereby creating respective node(s) representing the said digital file(s) (7001). The required nodes representing digital file(s) are selected for changing its state viz. data transformation/manipulation and/or visualization (7002) wherein data manipulation includes, without limitation, data extraction, wrangling, cleaning, preparation, statistical analysis; and said data visualization further includes generating figures of biological, chemical, medical and experimental data in the form of sequences, structures and models, to identify trends to gain a better understanding of the data. Similarly, upon application of such state change, a new node representing a modified state viz. an edge is created connecting the nodes and representing the state change (7003). If the process analysis is completed, the created workflow is saved (7004) else, the process of selecting a new digital file(s) material and creating respective nodes and edges are repeated (7005).

### REFERENCES

1. Baker, M. 1,500 scientists lift the lid on reproducibility. Nature 533, 452-454 (2016) [https://doi.org/10.1038/533452a]
2. But is the code (re)usable?. Nat Comput Sci 1, 449 (2021) [https://doi.org/10.1038/s43588-021-00109-9)]
3. Baker, M. Over half of psychology studies fail reproducibility test. Nature (2015) [https://doi.org/10.1038/nature.2015.18248]
4. Poldrack, R. The Costs of Reproducibility, Neuron Volume 101, Issue 1, 2 Jan. 2019, Pages 11-14 [https://doi.org/10.1016/j.neuron.2018.11.030]
5. eLife 2017; 6:e23693 DOI: 10.7554/eLife.23693, Mullard, A. Cancer reproducibility project yields first results. Nat Rev Drug Discov 16, 77 (2017) [https://doi.org/10.1038/nrd.2017.19]
6. Prinz, F., Schlange, T. & Asadullah, K. Believe it or not: how much can we rely on published data on potential drug targets?. Nat Rev Drug Discov 10, 712 (2011) [https://doi.org/10.1038/nrd3439-c1]
7. Bechhofer, S et. al. Why Linked Data is Not Enough for Scientists Future Generation Computer Systems 29(2), February 2013, Pages 599-611, ISSN 0167-739X [https://doi.org/10.1016/j.future.2011.08.004]
8. Ananthanarayanan, V., Thies, W. Biocoder: A programming language for standardizing and automating biology protocols. J Biol Eng 4, 13 (2010) [https://doi.org/10.1186/1754-1611-4-13]
9. Gupta V, Irimia J, Pau I, Rodríguez-Patón A. BioBlocks: Programming Protocols in Biology Made Easier. ACS Synth Biol. 2017 Jul. 21; 6(7):1230-1232 [doi: 10.1021/acssynbio.6b00304. Epub 2017 Jan. 24. PMID: 28051850]

1. A computer-implemented method for designing, planning, execution and analysis of a plurality of life science processes, for each such stage of the plurality of life science processes, the method comprising the steps of:
Specifying workflow using an input module, by way of adding a plurality of entities (101, 201) and/or batches of a plurality of entities (101, 201) wherein entities include physical materials and digital files;
Adding and applying information using a modification module, causing state change (102, 202) to the atleast one plurality of entities (101, 201) and/or batches of a plurality of entities (101, 201) to form its respective new entities (101′, 201′) with a modified state by way of specifying change specific parameters;
generating each of the plurality of processes of their respective stages in a graphical specification by a processing module, the graphical specification comprising a plurality of layers with layer-specific information, each said layer further includes a plurality of nodes (101, 201, 101′, 201′, 201″) and edges (102, 202, 203), wherein layer represents each stage of the process, node of any shape or size represents one entity and/or a batch of multiple entities including their states; and edge (102, 202, 203) represents information causing the state change in the entity and/or batch of multiple entities, wherein, (i) at least two processes are combined to form a complex process by way of merging and/or linking their boundary nodes for arrangement of the said processes in sequential order or to create a single process; (ii) at least one step in the at least one process of the plurality of processes is traversed by a certain pre-selected time point to minimize its execution time; and (iii) at least one process is automatically translated to a preferred natural language for further processing by a human; and
Storing the graphical specification of the plurality of processes in a database module for its easy retrieval at any point of time.

2. The method as claimed in claim 1 wherein the node (101, 201, 101′, 201′, 201″) includes a plurality of outgoing and incoming edges (102, 202, 203) connecting to their respective new states.

3. The method as claimed in claim 1 wherein physical materials are selected from a group comprising materials of biological, chemical and biomedical origin which include sub-cellular components, single or multicell organisms, tissues, organs, animals, patient samples, reagents, buffers, dyes, both individually or as complex mixtures, in solid, liquid or gaseous form.

4. The method as claimed in claim 1 wherein digital files are selected from a group comprising of biological data, chemical data, medical data and experimental data in any electronic format.

5. The method as claimed in claim 1 wherein change specific parameters for physical materials include quantity manipulation, transformation and measurement, said quantity manipulation further includes transfer, addition and deletion of similar or dissimilar quantities of the same or different materials; said transformation further includes moving, heating, cooling, separation and mixing of materials; and said measurement to investigate and estimate different biological, chemical and physical properties of materials further includes weighing, imaging, spectroscopy, sequencing and calorimetry.

6. The method as claimed in claim 1 wherein change specific parameters to digital files include data manipulation and visualization, said data manipulation further includes data extraction, wrangling, cleaning, preparation, statistical analysis; and said data visualization further includes generating figures of biological, chemical, medical and experimental data in the form of sequences, structures and models, to identify trends to gain a better understanding of the data.

7. The method as claimed in claim 1 wherein the change specific parameters are used by physical devices as input specifications for physical entities or by software applications as input specifications for digital entities.

8. The method as claimed in claim 1 wherein entities are mapped to materials or data; and data and the change specific parameters are mapped to compatible instruments and software applications during the planning stage of the process.

9. The method as claimed in claim 1 wherein the process are cyclical, acyclical or direct.

10. The method as claimed in claim 1 wherein plurality of nodes (101, 201, 101′, 201′, 201″) representing different types of entities are joined together to create longer complex processes.

11. The method as claimed in claim 1 wherein merging of the at least two processes includes overwriting a final state node (301″) of one process by an initial state node (401) of the other process.

12. The method as claimed in claim 1 wherein linking of the at least two processes includes connecting a final state node (301″) of one process to an initial state node (401) of the other process.

13. The method as claimed in claim 1 wherein the initial state node of a process is replaced with another entity of the same type.

14. The method as claimed in claim 1 wherein the process is traversed subject to conditions specified, the said conditions include parameters to be satisfied for further traversal of the process.

15. The method as claimed in claim 1 wherein the process is traversed subject to conditions specified, the said conditions include explicit approval required by a user for further traversal of the process.

16. The method as claimed in claim 1 wherein at least one process is automatically translated to preferred computer language for further processing by a compatible robotic platform.

17. The method as claimed in claim 1 wherein instrument-specific execution instructions are automatically sent to instruments during process execution.

18. The method as claimed in claim 17 wherein all data generated during the process execution is stored in the context of the respective edge and is represented on the node.

19. The method as claimed in claim 18 wherein the data is visualised and analysed in the analysis stage using configurable virtual machines deployed on the cloud or locally.

20. A computer-implemented system for designing, planning, execution and analysis of a plurality of life science processes, for each such stage of the plurality of life science processes, the system comprising:
an input module associated with server, wherein the input module enables specifying workflow by way of adding a plurality of entities (101, 201) and/or batches of a plurality of entities (101, 201) wherein entities include physical materials and digital files;
a modification module associated with the server, wherein the modification module enables adding and applying information causing state change (102, 202) to the atleast one plurality of entities (101, 201) and/or batches of a plurality of entities (101, 201) to form its respective new entity (101′, 201′) with a modified state by way of specifying change specific parameters;
a processing module associated with the server wherein the processing module enables generation of each of the plurality of processes of their respective stages in a graphical specification comprising a plurality of layers with layer-specific information, each said layer further includes a plurality of nodes (101, 201, 101′, 201′, 201″) and edges (102, 202, 203), wherein layer represents each stage of the process, node of any shape or size represents one entity and/or a batch of multiple entities including their states; and edge (102, 202, 203) represents information causing the state change in the entity and/or batch of multiple entities, wherein (i) at least two processes are combined to form a complex process by way of merging and/or linking their boundary nodes for arrangement of the said processes in sequential order or to create a single process; (ii) at least one step in the at least one process of the plurality of processes is traversed by a certain pre-selected time point to minimize its execution time; and (iii) at least one process is automatically translated to a preferred natural language for further processing by a human; and
a database module associated with the server for storing the graphical specification of the plurality of processes for its easy retrieval at any point of time.

21. The system as claimed in claim 20 wherein the node (101, 201, 101′, 201′, 201″) includes a plurality of outgoing and incoming edges (102, 202, 203) connecting to their respective new states.

22. The system as claimed in claim 20 wherein physical materials are selected from a group comprising materials of biological, chemical and biomedical origin including sub-cellular components, single or multicellular organisms, tissues, organs, animals in whole or in parts, patient samples, reagents, buffers, dyes, individually or as complex mixtures thereof, in solid, liquid or gaseous form.

23. The system as claimed in claim 20 wherein digital files are selected from a group comprising of biological data, chemical data, compound libraries and experimental data in any electronic format.

24. The system as claimed in claim 20 wherein change specific parameters for physical materials include quantity manipulation, transformation and measurement, said quantity manipulation further includes transfer, addition and deletion of similar or dissimilar quantities of the same or different materials; said transformation further includes moving, heating, cooling, separation and mixing of materials; and said measurement to investigate and estimate different biological, chemical and physical properties of materials further includes weighing, imaging, spectroscopy, sequencing and calorimetry.

25. The system as claimed in claim 20 wherein change specific parameters to digital files include data manipulation and visualization, said data manipulation further includes data extraction, wrangling, cleaning, preparation, statistical analysis; and said data visualization further includes generating figures of biological, chemical, medical and experimental data in the form of sequences, structures and models, to identify trends to gain a better understanding of the data.

26. The system as claimed in claim 20 wherein the set of change specific parameters are used by physical devices as input specifications for physical entities or by software applications as input specifications for digital entities.

27. The system as claimed in claim 20 wherein entities are mapped to materials or data; and the change specific parameters are mapped to compatible instruments and software applications during the planning stage of the process.

28. The system as claimed in claim 20 wherein the process is cyclical, acyclical or direct.

29. The system as claimed in claim 20 wherein plurality of nodes (101, 201, 101′, 201′, 201″) representing different types of entities are joined together to create longer complex processes.

30. The system as claimed in claim 20 wherein merging of the atleast two processes includes overwriting a final state node (301″) of one process by an initial state node (401) of the other process.

31. The system as claimed in claim 20 wherein linking of the at least two processes includes connecting a final state node (301′) of one process to an initial state node (401) of the other process.

32. The system as claimed in claim 20 wherein the initial state node of a process is replaced with another entity of the same type.

33. The system as claimed in claim 20 wherein the process is traversed subject to conditions captured as a part of edges, the said conditions include parameters to be satisfied for further traversal of the process.

34. The system as claimed in claim 20 wherein the process is traversed subject to conditions specified, the said conditions include explicit approval required by a user for further traversal of the process.

35. The system as claimed in claim 20 wherein the processes are automatically translated to preferred computer language for further processing by a compatible robotic platform.

36. The system as claimed in claim 20 wherein instrument-specific execution instructions are automatically sent to instruments during process execution.

37. The system as claimed in claim 36 wherein all data generated during the process execution is stored in the context of the respective edge and is represented on the node.

38. The system as claimed in claim 37 wherein the data is visualised and analysed in the analysis stage using configurable virtual machines deployed on the cloud or locally.
